(19) United States
(12) Patent Application Publication
(10) Pub. No.: US 2026/0313925 A1
(43) Pub. Date: Oct. 8, 2026

(54) A Multi-Layer Deep-Trench Capacitor

(71) Applicant: Lotus Microsystems ApS, Hvidovre (DK)

(72) Inventors: Hoà Lê Thanh, Hvidovre (DK); Ömer Altan, Hvidovre (DK); Ahmed Morsi Ammar; Yasser A. A. Nour, Hvidovre (DK)

(21) Appl. No.: 19/478,432

(22) PCT Filed: Apr. 25, 2024
(86) PCT No.: PCT/EP2024/061464

§ 371 Date: Oct. 24, 2025

(30) Foreign Application Priority Data
Apr. 25, 2023 (EP) 23169932.3

(51) Int. Cl. H10D 1/68; H10D 1/00; H10D 80/20; H10D 84/00; H10W 20/20

(52) U.S. Cl. CPC H10D 1/716; H10D 1/042; H10D 1/696; H10D 1/714; H10D 84/212; H10D 80/215; H10W 20/211

(57) ABSTRACT

The invention regards an integrated capacitor on a substrate comprising at least one trench within the substrate; a multilayer stack comprising at least three electrically conductive layers deposited on the substrate and separated by electrically isolative layers, and wherein the multilayer stack comprises a first set of odd layers and a second set of even layers, and wherein the multilayer stack is arranged in both a substantially vertical and a substantially horizontal direction along a plurality of surfaces of the substrate; at least a first and a second terminal, wherein the first terminal is in contact with the first set of odd layers and the second terminal is in contact with the second set of even layers. A method of manufacturing an integrated capacitor and a method for manufacturing a via connecting at least two layers comprised in a multilayer stack of at least three layers arranged on a substrate are also disclosed as well as various implementations of the integrated capacitor.

### BACKGROUND

The present disclosure relates to an integrated capacitor comprising a multilayer stack arranged such that the capacitor comprises a deep trench.

Integrated capacitors are passive electronic components that are commonly used in microelectronic circuits. Capacitors store electrical energy by accumulating charges on two parallel plates separated by an insulating material, called a dielectric. In microelectronic circuits, integrated capacitors are used for a variety of purposes, such as filtering out unwanted noise, providing power supply decoupling, and tuning circuit resonant frequencies. Integrated capacitors can be fabricated using various materials and structures, including metal-oxide-semiconductor (MOS) capacitors, metal-insulator-metal (MiM) capacitors, and thin-film capacitors.

MOS capacitors are formed by creating a sandwich structure of a metal electrode, a dielectric layer, and a semiconductor substrate. The capacitance of MOS capacitors can be controlled by adjusting the thickness and dielectric constant of the dielectric layer, as well as the surface area of the metal electrode. MiM capacitors, on the other hand, are composed of two metal electrodes separated by a dielectric material. The capacitance of MiM capacitors can be adjusted by changing the thickness and dielectric constant of the dielectric layer, as well as the surface area of the metal electrodes. Thin-film capacitors are made by depositing thin layers of metal and dielectric materials on a substrate. The capacitance of thin-film capacitors can be adjusted by changing the thickness and dielectric constant of the dielectric layer, as well as the surface area of the metal electrodes.

Each types of capacitors has its own advantages and drawbacks. While a MiM capacitor exhibits one of the highest capacitance density of the market, it suffers from a relatively low breakdown voltage, thereby making it useless for high voltage applications. Moreover, the manufacturing of such capacitors requires a relatively high amount of masks. Masks are patterned layers which are used to selectively define regions on a substrate where various materials or structures will be deposited or removed during the manufacturing process. Masks are typically made of a thin material, such as glass or chrome, and contain openings or “windows” in specific locations that allow light or other forms of energy to pass through and selectively pattern the underlying layer. The pattern on the mask is transferred to the substrate using a process called lithography. Masks are usually expensive and therefore limiting masks during a manufacturing process is critical in order to reduce costs. Moreover, when using multiple masks, manufacturing time can drastically increase since each mask requires a proper alignment and some additional steps which must be performed in series.

Deep-trench capacitor is another type of capacitor, where the layers are arranged within a trench, preferably etched in the semiconductor substrate. It provides a very high capacitance density since the area is maximized by using the three dimensions offered by a semiconductor substrate. On the other hand, the deep-trench capacitor suffers from an amount of layers which is often limited to two, and the manufacturing of the deep-trench capacitor requires different masks for creating connection points. It also suffers from a breakdown voltage which is limited by the thickness of the dielectric separating the metal layers, which in most cases remains thin.

### SUMMARY

Thus, there exists a need for an integrated capacitor with more than two layers, where the capacitance density is maximized and may use a limited number of masks in order to create the connection points or contacts during fabrication or manufacturing. A breakdown voltage may also advantageously be high enough to sustain high voltage applications.

As disclosed here, this can be achieved by an integrated capacitor on a substrate comprising at least one trench within the substrate; a multilayer stack comprising at least three electrically conductive layers deposited on the substrate and separated by electrically isolative layers, and wherein the multilayer stack comprises a first set of odd layers and a second set of even layers, and wherein the multilayer stack is arranged in both a substantially vertical and a substantially horizontal direction along a plurality of surfaces of the substrate; at least a first and a second terminal, wherein the first terminal is in contact with the first set of odd layers and the second terminal is in contact with the second set of even layers.

The integrated capacitor comprises at least three electrically conductive layers separated by electrically isolative layers, which gives the capacitor a high capacitance value. Advantageously, the integrated capacitor may comprise at least five, at least ten or at least twenty layers. The more layers, the more capacitance can be achieved within the same area.

By having at least one trench, the integrated capacitor provides a larger area where the multilayer stack is deposited, thereby increasing the capacitance value as well as maximizing capacitance density. Capacitance density is a measure of the amount of electrical charge that can be stored per unit area of a capacitor. The greater this value, the greater the capacitance value for a given unit area of a capacitor.

The multilayer stack is both deposited on top of the substrate, but also within the at least one trench, such that the electrically conductive layers and the electrically isolative layers are deposited on the sidewalls and the trench bottom of the at least one trench arranged within the substrate. This structure advantageously allows a relatively simple deposition process, and allows a relatively large thickness of the electrically isolative layers. This may improve the breakdown voltage of the integrated capacitor as disclosed herein.

In another aspect, a method of manufacturing an integrated capacitor on a substrate is disclosed. The method comprises the steps of creating at least one trench in the substrate; arranging a multilayer stack on the substrate comprising at least three electrically conductive layers and separated by electrically isolative layers, and wherein the multilayer stack comprises a first set of odd layers and a second set of even layers, and wherein the multilayer stack is arranged in both a substantially vertical and a substantially horizontal direction along a plurality of surfaces of the substrate; creating at least two trenches in the multilayer stack down to a lowest layer of the multilayer stack, thereby defining at least a first and a second terminal trench; removing a substantial portion of the first set of odd layers within the first terminal trench; removing a substantial portion of the second set of even layers within the second terminal trench; arranging a secondary electrically conductive layer on the multilayer stack, and wherein the secondary electrically conductive layer is further arranged within the at least first and second terminal trench and in contact with the first set of odd layers and the second set of even layers; removing a substantial part of the secondary electrically conductive layer such that the first terminal is electrically isolated from the second terminal.

By creating at least two trenches in the multilayer stack down to a lowest layer of the multilayer stack, only one mask is needed to perform this step, where the same mask can be reused to perform the following steps of the method such as removing a substantial portion of the first set of odd layers within the first terminal trench; removing a substantial portion of the second set of even layers within the second terminal trench; arranging a secondary electrically conductive layer on the multilayer stack, and wherein the secondary electrically conductive layer is further arranged within the at least first and second terminal trench and in contact with the first set of odd layers and the second set of even layers.

Removing a substantial portion of the first set of odd layers within the first terminal trench can be achieved by having the first set of odd layers having different properties than the second set of even layers. Removing a substantial portion of the second set of even layers within the second terminal trench can be achieved by having the second set of even layers having different properties than the first set of odd layers. Advantageously, a selective etch can be performed by using an appropriate etchant, based on the property that needs to be etched, either the property of the first set of odd layers or the property of the second set of even layers.

The secondary electrically conductive layer can then be deposited on the multilayer stack, wherein the secondary electrically conductive layer is in contact with both the first set of odd layers within the first terminal trench and the second set of even layers within the second terminal trench. By removing a substantial part of the secondary electrically conductive layer such that the first terminal trench is electrically isolated from the second terminal trench, an integrated capacitor with a high capacitance density can be achieved.

In one aspect, a method of manufacturing a via connecting at least two layers comprised in a multilayer stack of at least three layers arranged on a substrate is disclosed where the method comprises the steps of: arranging a multilayer stack on the substrate comprising at least three electrically conductive layers and separated by electrically isolative layers, and wherein the multilayer stack comprises a first set of odd layers and a second set of even layers; creating at least one trench in the multilayer stack down to a lowest layer of the multilayer stack; removing a substantial portion of the first set of odd layers or the second set of even layers through the at least one trench; arranging a secondary electrically conductive layer on the multilayer stack, and wherein the secondary electrically conductive layer is further arranged within the at least one trench and in contact with the first set of odd layers or the second set of even layers.

By selectively removing a substantial portion of the first set of odd layers or the second set of even layers, an electrical isolation between the first set of odd layers and the second set of even layers can be achieved. Advantageously, only one mask may be required to manufacture the via connecting the at least two layers comprised in the multilayer stack. This reduces the manufacturing time as well as the number of masks required to process such a connection between the at least two layers.

In yet another aspect, an integrated capacitor device comprising the integrated capacitor as disclosed herein and at least two external terminals, wherein the at least two external terminals are connected to the at least first and second terminals of the integrated capacitor as disclosed herein.

In a different aspect, an integrated capacitor device comprises at least one integrated capacitor as disclosed herein; one or more vias, such as through substrate vias, arranged in the substrate and connected to the at least first and second terminals of the at least one integrated capacitor as disclosed herein, and wherein the through substrate vias provide a plurality of terminals on both sides of the substrate.

In another aspect, an integrated circuit assembly comprises at least one integrated circuit; at least one integrated capacitor as disclosed herein; wherein the at least one integrated circuit and the at least one integrated capacitor are integrated and electrically connected in the substrate, and wherein the integrated circuit assembly further comprises at least two external terminals.

In one aspect, an integrated circuit assembly comprises at least one integrated circuit; at least one integrated capacitor as disclosed herein; one or more vias, such as through substrate vias, arranged in the substrate and connected to the at least first and second terminals of the at least one integrated capacitor as disclosed herein and/or to the at least one integrated circuit, and wherein the through substrate vias provide a plurality of external terminals on both sides of the substrate.

### DESCRIPTION OF THE DRAWINGS

In the following embodiment and examples will be described in greater detail with reference to the accompanying drawings:

FIG. 1A-B show embodiments of schematic views of the integrated capacitor,

FIG. 2A-B show an embodiment of a 3D view of an integrated capacitor with two terminals, where the integrated capacitor comprises a plurality of interlayer vias, and a schematic view of the top view of the embodiment of a 3D view of the integrated capacitor and a cross section A-A′ of the top view,

FIG. 3 shows an embodiment of a schematic view of the steps of the method as disclosed in the current disclosure for thin electrically conductive layers,

FIG. 4 shows an embodiment of a schematic view of the steps of the method as disclosed in the current disclosure for thick electrically conductive layers,

FIG. 5 shows an embodiment of a schematic view of two cases, where a first case shows an embodiment of a schematic view where one of the terminals has an ohmic contact with the substrate and a second case shows an embodiment of a schematic view where both terminals have a substrate isolation,

FIG. 6A-B show embodiments of schematic views of the integrated capacitor with external terminals, where the external terminals are arranged on one side, and on both sides of the substrate with through substrate vias,

FIG. 7A-C show embodiments of schematic views of the integrated capacitor integrated with an integrated circuit in a substrate,

FIG. 8A-B show embodiments of schematic views of possible applications of the integrated capacitor in stacked electronic assembly,

FIG. 9A-I show embodiments of schematic views of possible applications of the integrated capacitor in stacked electronic assembly.

FIG. 10A-B show an embodiment of a schematic view of the integrated capacitor seen from a cross section of a side view and a top view, wherein the embodiment of the integrated capacitor comprises through-substrate vias and redistribution layers on both sides of the substrate.

FIG. 11 shows an embodiment of a schematic view of the integrated capacitor, comprising multiple trenches and through substrate vias connecting redistribution layers arranged on both sides of the substrate.

### DETAILED DESCRIPTION

In the context of this patent application, it is important to note that when the terms “is made of”, “can be made of”, “is made with”, “can be made with”, are used to describe the composition of a component or material, they are not intended to be limiting. Rather, these phrases are employed to indicate examples of materials or components that are suitable for use in the invention. The use of “is made of”, “can be made of”, “is made with”, “can be made with”, should be understood to encompass any equivalent materials or components that serve the same or similar function without departing from the scope of the invention. Thus, the phrases “is made of”, “can be made of”, “is made with”, “can be made with”, are to be construed in a manner consistent with the concept of “comprising”, indicating that the invention may include additional elements or materials beyond those specifically mentioned.

The present disclosure discloses an integrated capacitor on a substrate that may comprise at least one trench; a multilayer stack that can comprise at least three electrically conductive layers and separated by electrically isolative layers, and wherein the multilayer stack may comprise a first set of odd layers and a second set of even layers; at least a first and a second terminal, wherein the first terminal can be in contact with the first set of odd layers and the second terminal may be in contact with the second set of even layers.

The substrate may be a semiconductor substrate, a glass substrate, a sapphire substrate or a polyamide substrate. The semiconductor substrate may be made of a semiconductor material such as silicon, germanium, or gallium arsenide, which can have specific electrical properties that may allow it to be used in the construction of electronic devices. The properties of the substrate, such as its conductivity, resistivity, and bandgap, can be critical to the performance of the electronic components that are built on top of it. Other substrates such as glass substrate, sapphire substrate or polyamide substrate can also be used.

The multilayer stack may comprise at least four, preferably at least five, more preferably at least ten, even more preferably at least fifteen, most preferably at least twenty electrically conductive layers. Adding more layers in the multilayer stack can increase the capacitance of the integrated capacitor. Advantageously, each additional layer may add more surface area to the capacitor, thereby increasing the amount of charge that can be stored. Preferably, adding layers may improve voltage rating of the integrated capacitor, such as its voltage breakdown. The voltage can be distributed across multiple layers, thereby reducing stress on each individual layer. Adding multiple layers to the multilayer stack can also help reducing the area of the integrated capacitor. For a same area, having more layers can give a higher capacitance, thereby maximizing the capacitance density.

In a preferred embodiment, the integrated capacitor comprises at least two trenches, preferably at least three trenches, more preferably at least four trenches within the substrate. By adding more trenches in the substrate, the surface area on which the multilayer stack is deposited may be extended. Advantageously, each trench provides an additional dimension to the multilayer stack such as the area of the multilayer stack is maximized in the substrate.

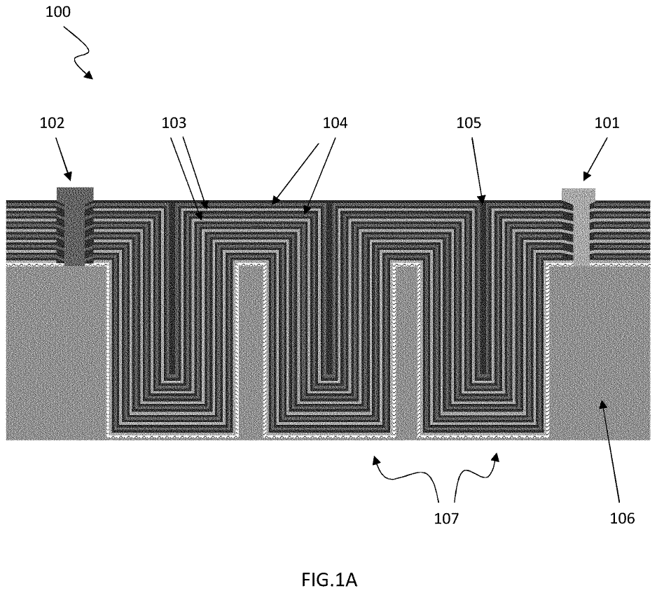

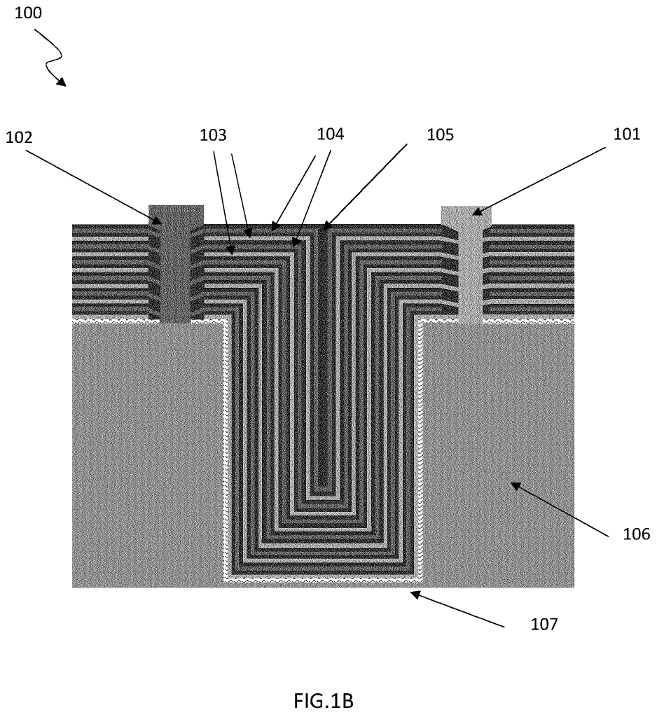

FIG. 1A-B show embodiments of schematic views of the integrated capacitor. FIG. 1A shows an embodiment of a schematic view of the integrated capacitor 100. The integrated capacitor 100 comprises three trenches 107 in the substrate 106. The multilayer stack is arranged on the substrate and further within the three trenches. The multilayer stack comprises 12 layers, with the first set of odd layers 103 comprising 6 layers and the second set of even layers 104 comprising 6 layers. The multilayer stack comprises a dielectric 105, which separates the layers. The first set of odd layers is connected to the first terminal 101 while the second set of even layers is connected to the second terminal 102. The first and the second terminals are vias, which are filled with metal. A contact is further deposited on top of the vias in order to allow an electrical connection from the vias. As shown in FIG. 1A, the three trenches allows the multilayer stack length to be increased compared to an integrated capacitor where no trenches would be processed in the substrate. This advantageously allows a higher capacitance on the same surface or area. FIG. 1B shows an embodiment of a schematic view of the integrated capacitor 100. The integrated capacitor 100 comprises one trench 107 in the substrate 106. The multilayer stack is arranged on the substrate and further within the trench. The multilayer stack comprises 12 layers, with the first set of odd layers 103 comprising 6 layers and the second set of even layers 104 comprising 6 layers. The multilayer stack comprises a dielectric 105, which separates the layers. The first set of odd layers is connected to the first terminal 101 while the second set of even layers is connected to the second terminal 102. The first and the second terminals are vias, which are filled with metal. A contact is further deposited on top of the vias in order to allow an electrical connection from the vias.

The integrated capacitor may comprise at least three terminals, preferably at least five terminals, more preferably at least ten terminals, even more preferably at least twenty terminals. Advantageously, more terminals may decrease the equivalent series resistance (ESR) of the integrated capacitor. Preferably, the terminals connected to the first set of odd layers may be connected together and the terminals connected to the second set of even layers can be connected together. By connecting the terminals connected to the same set of layers, preferably with a low-ohmic electrical connection, this may allow the equivalent series resistance of the integrated capacitor to be substantially reduced.

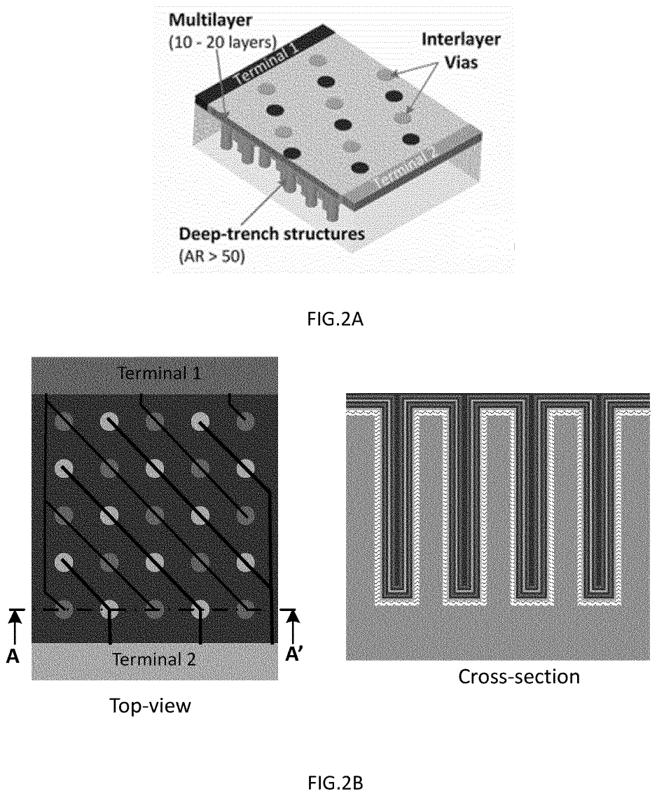

FIG. 2A shows an embodiment of a 3D view of an integrated capacitor with two terminals, but where the integrated capacitor comprises a plurality of interlayer vias. The interlayer vias are arranged in order to reduce or minimize the ESR. The interlayers vias connected to the first set of odd layers are electrically connected together and further connected to the terminal 1, and the second set of even layers are electrically connected together and further connected to terminal 2. The integrated capacitor comprises more than 50 deep-trench structures, arranged in the substrate. FIG. 2B shows a schematic view of the top view of the embodiment of a 3D view of the integrated capacitor as shown in FIG. 2A, and a cross section A-A′ of the top view. The top view shows the electrical connection between the interlayer vias, further to terminal 1 or terminal 2. Via1 are the different vias that electrically connect the first set of odd layers of the multilayer stack and via2 are the different vias that electrically connect the second set of even layers of the multilayer stack. This is one example, and via1 can connect the second set of even layers while via2 may connect the first set of odd layers. Preferably, via1 connects one set of layers, i.e. odd or even, while via2 connect the other set of layers. The cross section illustrates the multilayer stack arranged on the substrate, in a substantially horizontal and vertical direction. The cross-section shows a multilayer stack comprising four layers but a person skilled in the art would understand that more layers can be easily arranged by having trenches with a larger width.

In one embodiment, the at least one trench have an opening width in the range of 0.1 μm to 10 μm. In a preferred embodiment, the at least one trench have a depth in the range of 10 μm to 725 μm. Preferably, the maximum depth of the at least one trench is substantially equal to the thickness of the substrate.

The at least first and second terminal may be vias. The vias can be filled with an electrically conductive metal or can be left unfilled. An unfilled via is a via that ensures connections between different layers, such as electrically conductive metal layers, without being filled. Preferably, the integrated capacitor may have at least three terminals, more preferably at least five terminals, even more preferably at least ten terminals. By having more terminals, the electrical series resistance of the integrated capacitor can be reduced. This is advantageous for applications where the series resistance needs to be minimized in the integrated capacitor. For instance, a high ESR can increase power consumption, reduce efficiency, causing higher operating temperatures, which can in the end lead to premature failure of the capacitor.

The terminals connecting the first set or the second set can be connected together in order to minimize the ESR of the integrated capacitor. The terminals can also be connected by groups, where at least a first group of terminals connecting the first set can be connected together while another group of terminals connecting the first set can be connected together. The terminals can be connected by groups for the second set, where at least a first group of terminals connecting the second set can be connected together while another group of terminals connecting the second set can be connected together.

The vias may have a redistribution layer. The vias may be comprised in the redistribution layer. The redistribution layer may be used to connect the vias with external devices such as one or more integrated circuits, one or more passive devices and/or one or more external terminals. External terminals may be the terminals used to connect the substrate to an external printed circuit board or another substrate. The external terminals may be bonded with wire bonds or connected via a flip-chip process.

The redistribution layer can be arranged on an upper surface of the vias, and the upper surface of the vias may be substantially arranged at the same height than an upper surface of the multilayer stack.

In one embodiment, the diameter of the vias is in the range of 1 to 50 μm.

In a preferred embodiment, the thickness of the redistribution layer is in the range of 1 to 30 μm.

The vias can be through-silicon vias (TSVs) or through-substrate vias. A through-substrate via is a vertical interconnect structure that passes through a substrate or semiconductor substrate to provide electrical connections between the front and the back sides of the die, substrate or semiconductor substrate.

The through-silicon vias as described herein can be through-substrate vias. Depending on the type of substrate, the through-silicon vias can be understood as through-substrate vias, if the through-substrate vias are vias crossing a substrate which may not be a silicon substrate.

The at least first and second terminal may be configured to be deposited with a secondary electrically conductive layer. The secondary electrically conductive layer can be made with copper (Cu). Copper can be preferred because it has good electrical conductivity and can be easily patterned and etched, preferably making it an ideal material for use in interconnects. Copper also can have good thermal conductivity, which may help dissipate heat. Some alternatives to copper may include aluminum and gold, which are also good conductors of electricity. Another advantage is that copper can be highly resistant to corrosion. The secondary electrically conductive layer may be deposited with any of the deposition methods as described in the current disclosure.

The secondary electrically conductive layer may be configured to be deposited with a seed layer comprising an adhesion layer made with an adhesion material such as chrome (Cr), titanium (Ti) or tantalum (Ta) and a seed metal layer made with a seed metal material such as copper (Cu), aluminium (Al) or gold (Au). The secondary electrically conductive layer can be deposited with an electroless nickel immersion gold (ENIG) method. A seed layer may be a thin film of a specific material that is deposited as the first step in a deposition process. The seed layer may be used as a nucleation site for the growth of additional layers of the same material, preferably via a process such as chemical vapor deposition (CVD) or physical vapor deposition (PVD). The purpose of the seed layer can be to ensure that the subsequent layers of the material grow uniformly and adhere well to the surface on which it may be deposited. The thickness of the seed layer is typically on the order of a few nanometers to a few micrometers, depending on the specific application.

The ENIG process may be used to deposit a thin layer of electroless nickel and a thin layer of gold onto the surface of the multilayer stack. The purpose of applying ENIG to the multilayer stack or preferably to any surfaces can be to provide a protective and corrosion-resistant coating that may ensure the long-term reliability of the structure.

The electroless nickel layer can serve as a barrier layer that may prevent diffusion between the different layers of the stack, while the gold layer can provide a flat and uniform surface that is suitable for bonding or soldering.

The electrically conductive layers may be made with copper (Cu), gold (Au), chrome (Cr), titanium (Ti), platinum (Pt), aluminium (Al), tantalum (Ta), titanium carbide (TiC), titanium nitride (TiN), tantalum (Ta), tantalum nitride (TaN), Ti-doped zinc oxide (TZO) and/or Al-doped zinc oxide (AZO). As described herein, the multilayer stack can comprise a first set of odd layers and a second set of even layers. Advantageously, the first set of odd layers and the second set of even layers may have different properties. One property may be that both sets may be made with different materials. Different materials may allow a selective etching of either the first set or the second set of layers comprised in the multilayer stack. The electrically conductive layers may preferably have a good conductivity in order to reduce the equivalent series resistance of the integrated capacitor. Preferably, the electrically conductive layer can be doped with elements or compounds. Doping is the process of intentionally adding impurities to a material to alter its properties. One example of copper doping is the addition of small amounts of silver or other elements to copper, which may create a material known as copper alloy. Copper alloys can have higher electrical conductivity than pure copper.

The electrically conductive layers can be configured to be deposited with a deposition method such as evaporation, sputtering or atomic layer deposition (ALD). The electrically conductive layers may also be deposited with physical vapour deposition, chemical vapour deposition or spin coating. Each deposition methods may have advantages and drawbacks compared to each other. Evaporation may be simple and low-cost, it can give a high purity and good adhesion to substrates and can depose a variety of materials, including metals and organic compounds, and can be suitable for both conductive and insulating layers. Evaporation may be limited to small area deposition due to the line-of-sight nature of the process, and can be limited for producing layers with precise thickness control. Sputtering can also deposit a variety of materials, and can produce thin films with precise thickness and uniformity. Sputtering can be used in large areas but may require a high equipment and maintenance costs, and may be limited to substrates that can withstand high temperature and/or reactive gases. ALD can provide a precise thickness control down to the atomic level, a high uniformity, can deposit a wide range of materials and may be suitable for depositing very thin films. It may provide low deposition rates compared to the other methods, and a high equipment and maintenance costs. The process time can also be drastically increase because of the ALD process which may require multiple deposition and reaction steps.

The thickness of the electrically conductive layers can be in the range of 5 to 500 nm. The thickness of the electrically conductive layers may be chosen depending on multiple criteria. A thicker layer may provide a lower equivalent series resistance and better mechanical properties. A thinner layer can provide better electrical conductivity and can also increase the capacitance density, since thinner layers may allow more layers to be fitted within the multilayer stack for a given space.

The electrically isolative layers can be dielectric layers. Each one of the electrically isolative layers comprised in the multilayer stack may have different thickness and different properties, such as different materials. One or more of the dielectric layers can preferably be a non-conductive material. A dielectric layer may have the ability to store electrical energy in the form of an electric field when a voltage may be applied across them. Advantageously, this property may make it useful in applications such as capacitors or integrated capacitors. A dielectric layer can be used as the insulating material, or isolative material, between two electrically conductive layers of the multilayer stack, allowing the integrated capacitor to store charge without discharging through the dielectric layer.

In one embodiment, the dielectric layer is made with silicon dioxide (SiO₂), silicon nitride (Si3N4), aluminium oxide (Al2O3), aluminium nitride (AlN), hafnium oxide (HfO2) or titanium dioxide (TiO2). Other materials which may present dielectric properties may be used as the dielectric layer. Preferably, the material used for the dielectric layer may be chosen in accordance with the materials used for the electrically conductive layers. The material for the dielectric layer and the materials for the electrically conductive layers may have to be compatible such as the integrated capacitor manufacturing process can remain possible and preferably quick and low-cost. The dielectric layer may be made or deposited with different materials in the same integrated capacitor.

The thickness of the dielectric layer can be in the range of 5 to 3000 nm. The thickness of the dielectric layer of the integrated capacitor may depend on the specific requirements of the application where the integrated capacitor can be used. Such requirements can be summarized below:
Capacitance value: The thickness of the dielectric layer can affect the capacitance value of the integrated capacitor. A thicker dielectric layer can result in a lower capacitance value, while a thinner dielectric layer may result in a higher capacitance value.
Breakdown voltage: The thickness of the dielectric layer can also affect the breakdown voltage of the integrated capacitor. A thicker dielectric layer can result in a higher breakdown voltage, while a thinner dielectric layer may result in a lower breakdown voltage.
Operating conditions: The operating conditions of the integrated capacitor, such as the voltage and temperature, can also affect the choice of the thickness of the dielectric layer. If the integrated capacitor can be subjected to high voltages, a thicker dielectric layer may be necessary to prevent breakdown.
Size constraints: In some applications, the available space for the capacitor may be limited, which can influence the choice of the dielectric layer thickness.
Cost: The cost of the dielectric material and the deposition process may also play a role in determining the thickness of the dielectric layer. Thicker layers may require more material and/or longer processing times, which can increase the cost of the device.

A dielectric layer may be arranged between two successive electrically conductive layers in the multilayer stack. Each dielectric layer comprised in the multilayer stack may have different thickness and different properties, such as different materials.

In one embodiment, the integrated capacitor comprises a secondary electrically isolative layer. The secondary electrically isolative layer may be arranged between the substrate and the multilayer stack. Preferably, the secondary electrically isolative layer can be an insulator layer. An insulator layer can be preferably used to provide an electrical isolation between the substrate and the layers deposited on top of the insulator layer. More generally, an insulator layer prevents unwanted electrical connections or short circuits from occurring.

The insulator layer can be made with silicon dioxide (SiO2), silicon nitride (Si3N4), aluminium oxide (Al2O3) or aluminium nitride (AlN). Other materials which may present insulator properties may be used as the insulator layer. Insulator properties may be the ability to provide electrical insulation.

The thickness of the insulator layer is in the range of 5 to 3000 nm. The thickness of the insulator layer may be chosen based on the specific requirements of the application in which it may be used such as integrated capacitors. Such requirements can be summarized below:
Voltage breakdown: The thickness of the insulator layer may need to be sufficient to withstand the maximum voltage that will be applied across it without breaking down. The voltage breakdown strength of the insulator material can be measured and used to calculate the minimum required thickness.
Parasitic capacitance: The thickness of the insulator layer can be used to decrease the capacitive coupling to the substrate. The capacitance of a capacitor is proportional to the area of the plates and inversely proportional to the distance between them. Therefore, a thicker insulator layer will result in a lower parasitic capacitance.
Process constraints: The thickness of the insulator layer may be limited by the deposition method or the process used to create it. For example, certain deposition techniques may not be able to produce insulator layers that are thicker than a certain amount.
Mechanical considerations: The thickness of the insulator layer may also be influenced by mechanical factors such as the need for the layer to provide structural support, or to prevent delamination or cracking.

The electrically isolative layers may be configured to be deposited with a secondary deposition method such as thermal oxidation, evaporation, sputtering, atomic layer deposition or chemical vapor deposition (CVD). The chemical vapour deposition may be used for depositing thin layers of material onto a substrate. The chemical vapour deposition method may provide high purity, precise control and scalability. It can be relatively more complex than the other deposition methods, since it may require careful control of multiple parameters, such as temperature, pressure, gas flow rates, and the CVD method can be limited by the substrate properties. CVD may require a clean and smooth substrate surface, which can limit the types of substrates that can be used and may add to the cost of the process.

The semiconductor substrate can be a silicon substrate, a gallium nitride (GaN) substrate, a silicon carbide (SIC) substrate or a gallium arsenide (GaAs) substrate.

The thickness of the substrate is in the range of 50 to 750 μm. The thickness of the substrate may be chosen depending on specific requirements of the application such as a capacitor application and the properties of the substrate material. The substrate thickness can be chosen to ensure mechanical stability and prevent warping or bending during processing and use. The substrate thickness can affect the thermal conductivity of the integrated capacitor, which can impact heat dissipation. Thicker substrates may generally have higher thermal conductivity, but may also increase thermal resistance and reduce heat dissipation. Different substrate materials have different mechanical, thermal, and electrical properties, which can impact the optimal substrate thickness. For example, SiC substrates may have higher thermal conductivity than Si substrates, which may allow for thinner substrates to be used for an equivalent thermal dissipation. Advantageously, the substrate thickness may be chosen to ensure compatibility with the fabrication process and equipment. Thicker substrates may require longer processing times and higher temperatures, which can impact the quality and yield of the device.

The integrated capacitor can further comprise a diffusion barrier layer. The diffusion barrier layer can be arranged between the insulator layer and the multilayer stack. The diffusion barrier layer may have a thickness in the range of 5 to 100 nm. The diffusion barrier layer may be used to avoid temperature or current-driven diffusion of conductive elements into the substrate. This would cause the performance of the integrated capacitor to be degraded due to increase substrate parasitic coupling.

In one embodiment, the at least one trench is at least one through substrate trench, and wherein the at least one through substrate trench is configured to be etched through the substrate. The at least one through substrate trench can be etched with several methods, such as wet etching, dry etching, and other hybrid methods such as reactive ion etching or deep reactive ion etching. The at least one through substrate trench may be etched on predefined through substrate trench areas, wherein the predefined through substrate trench areas can be defined by a through substrate trench photomask. The at least one trench can be etched on predefined trench areas, wherein the predefined trench areas can be defined by a trench photomask. The trench photomask can be the through-substrate trench photomask. It may be advantageous to have one photomask defining both the predefined through substrate trench areas and the predefined trench areas. The at least one through substrate trench can be etched from one side of the substrate to the other side of the substrate.

The multilayer stack can be configured to be deposited on a first side and a second side of the substrate. Advantageously, the multilayer stack can be deposited on the first side and the second side of the substrate in one process if atomic layer deposition can be used. The multilayer stack can be deposited on a first side of the substrate, then the substrate can be flipped in order to deposit the multilayer stack on the second side of the substrate.

The first side and the second side of the substrate can be opposite sides of the substrate. The first side can be the top of the substrate and the second side can be the bottom of the substrate. The first side can be the bottom of the substrate and the second side can be the top of the substrate.

In a preferred embodiment, the multilayer stack is configured to be deposited on lateral surfaces of the at least one through substrate trench, and such as the multilayer stack is configured to be connected from the first side to the second side through the at least one through substrate trench. Preferably, the at least one trench and/or the at least one through substrate trench can be etched before depositing the multilayer stack. The multilayer stack can be subsequently deposited with a deposition method such as atomic layer deposition, which would deposit the multilayer stack in at least the first side of the substrate as well as the lateral sides of the at least one through substrate trench and/or the lateral sides of the at least one trench.

The lateral surfaces of the at least one through substrate trench may be inner lateral surfaces of the at least one through substrate trench. The inner lateral surfaces of the at least one through substrate trench may be defined as through substrate trench sidewalls or simply sidewalls. This may emphasize their role as the vertical or sloped surfaces that delineate the through substrate trench cavity. It may be understood throughout this patent application that the same terms may be applied to the at least one trench when defining the sidewalls of the at least one trench, which can be defined as inner surfaces or sidewalls, as described in this paragraph.

In one embodiment, the at least one through substrate trench is configured to be filled with a through-substrate via material, such as the substrate comprises at least one through-substrate via. The at least one through-substrate via material may be filled with a through-substrate via material such as copper, tungsten, gold, silver, nickel, graphene or any combinations thereof. The at least one through substrate trench can be fully filled with the through-substrate via material. Preferably, the entire void or cavity of the at least one through substrate trench can be completely filled with the through-substrate via material. Advantageously, fully filled vias can be preferred where high electrical conductivity, low resistance and good mechanical stability are critical. As soon as the at least one through substrate trench is filled with a through-substrate material, at least one through-substrate via can be created within the substrate. The at least one through-substrate via can connect, both electrically and thermally, the first side of the substrate with the second side of the substrate. Advantageously, the through-substrate via material can present a high thermal conductivity as well as a high electrical conductivity, thereby helping the substrate to dissipate heat from one side to the other side of the substrate, such as from the first side to the second side or vice versa.

The at least one through-substrate via may be configured to be connected to the redistribution layer. The at least one through-substrate via may be electrically connected to the redistribution layer. Advantageously, the redistribution layer and the through-substrate via comprises the same material, or materials that can be compatible such as an efficient electrical conductivity can occur between the at least one through-substrate via and the redistribution layer.

The redistribution layer (RDL) can comprise a first redistribution layer and a second redistribution layer. The redistribution layer can be segmented or partitioned into multiple subsections, wherein each subsections may serve distinct functional roles such as signal routing, power distribution and/or grounding. This partitioning may enable an efficient management of electrical connections and may allow for optimized routing of signals and power. The redistribution layer may be used for several purposes such as signal routing, power distribution, grounding and/or isolation.

Different portions of the RDL may be dedicated to routing signals to various locations on the substrate. This can allow for efficient and optimized routing of signals, such as signals to and from the integrated capacitor. Sections of the RDL can be designated for distributing power to different areas, ensuring that power is delivered efficiently and with minimal impedance. Separate parts of the RDL can be used for grounding purposes, providing low impedance paths for grounding signals and reducing noise in the system. For instance, the first and/or the second terminal of the integrated capacitor can be routed to a ground, wherein the impedance between the first and/or the second terminal and the ground should be minimized. An efficient routing through the RDL can efficiently provide a minimal impedance to the ground to the first and/or the second terminal of the integrated capacitor. This can advantageously be used in the case of efficient local decoupling to ground. Isolation can be achieved between different signal or power domains by dividing the RDL into multiple parts, reducing crosstalk and interference between different parts of the substrate.

The first redistribution layer can be arranged on the first side of the substrate and the second redistribution layer may be arranged on the second side of the substrate.

The redistribution layer can comprise the at least first and/or second terminal. The at least first and/or second terminal can be the terminals of the integrated capacitor as defined in the present disclosure. Thereby, the redistribution layer can connect the first and/or second terminal of the integrated capacitor to secondary devices arranged on the substrate or to pads disposed or arranged on the substrate in order to connect the integrated capacitor to external devices or substrates.

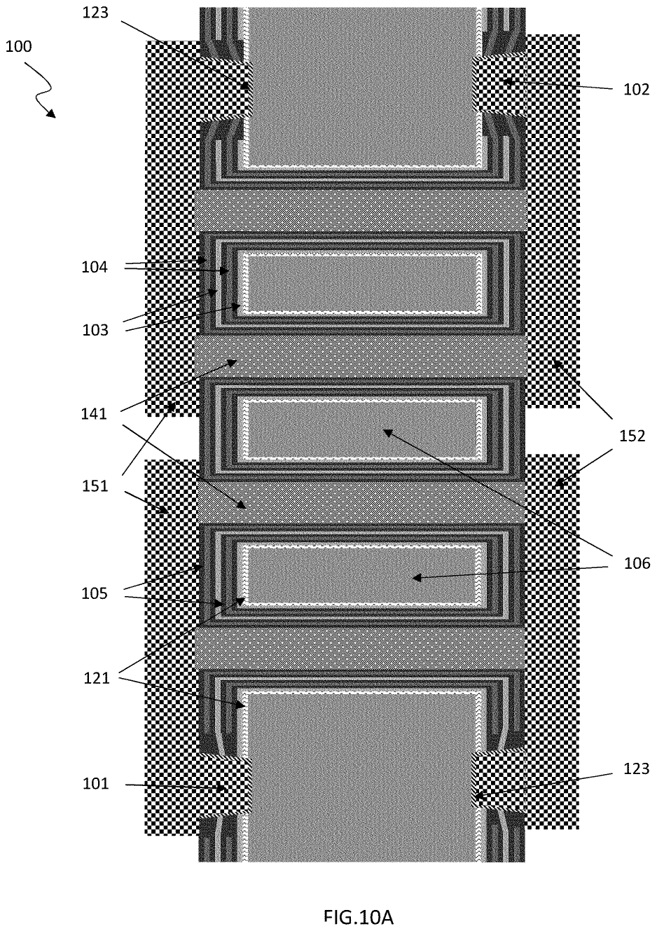

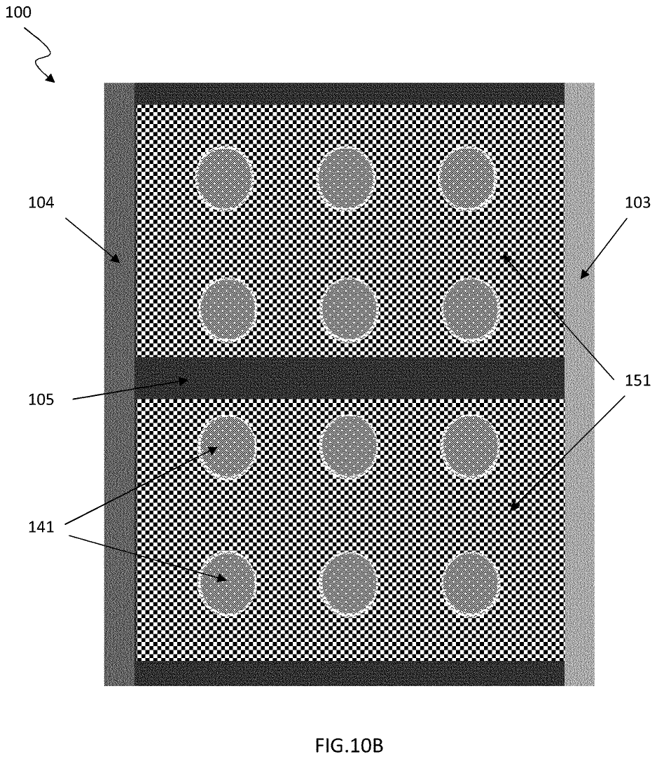

FIG. 10A-B show an embodiment of a schematic view of the integrated capacitor 100 seen from a cross section of a side view and a top view, wherein the embodiment of the integrated capacitor 100 as shown in FIG. 10A-B comprises through-substrate vias 141 and redistribution layers 151 152 on both sides of the substrate. FIG. 10A shows a substrate 106 wherein at least one through substrate vias 141 are comprised within the substrate 106. Four through substrate vias 141 are arranged within the substrate 106. The multilayer stack is deposited on both sides of the substrate 106 as well as on the inner surfaces of the at least one through substrate trenches, or vias 141. This advantageously maximize the area where the odd layers 103 and the even layers 104 are close to each other, thereby maximizing the capacitance of the integrated capacitor 100 in a given area of the substrate 106. In this embodiment, 4 layers are arranged in the multilayer stack but more layers could be arranged to increase the capacitance of the integrated capacitor 100. A dielectric layer 105 is arranged between the layers to provide electrical isolation. The dielectric layer is the dielectric layer as described in the present disclosure. The multilayer stack is arranged on an insulator layer 121, such as the insulator layer is arranged between the substrate 106 and the first layer of the multilayer stack. The first layer of the multilayer stack is the bottom layer of the multilayer stack, which is the closest layer to the substrate. The multilayer stack comprises 4 layers, with the first set of odd layers 103 comprising 2 layers and the second set of even layers 104 comprising 2 layers. The multilayer stack comprises a dielectric layer 105, which separates the layers. The first set of odd layers 103 is connected to two first terminals 101 while the second set of even layers is connected to two second terminals 102. The first and the second terminals are vias, which are filled with metal. The first and the second terminals are directly connected to the redistribution layer 151 152. As shown in FIG. 10A, the redistribution layer comprises a first redistribution layer 151 and a second redistribution layer 152 arranged on both sides of the substrate 106. The two redistribution layers are electrically connected by the through-substrate vias 141. This embodiment allows a flexibility of the integrated capacitor 100. A large capacitance is achieved between the first 151 and the second redistribution layer 152. A flexibility in regards to the electrical connection is also achieved, since one port can be connected on the top side of the integrated capacitor while the other port can be connected to the bottom side of the integrated capacitor. This advantageously allows a flexibility for 3D integration of such integrated capacitor since the integrated capacitor can be connected to external devices from both sides, thereby allowing a stacking of electronic components. FIG. 10B shows a top view of the embodiment as described and shown in FIG. 10A. FIG. 10B shows the top view, wherein all through substrate vias 141 are seen from the top, and wherein the dielectric layer 105 covers the top of the substrate 106. The person skilled in the art understands that the odd and even layers are deposited below the dielectric layer 105, as shown in FIG. 10B. The top layer of the odd layers 103 and the top layer of the even layers 104 are exposed on the right side and the left side, respectively. The dielectric layer 105 can cover the exposed top layer of the odd layers 103 and the top layer of the even layers 104, such that no odd layers or even layers are exposed. Twelve through-substrate vias 141 are shown in FIG. 10B. More through-substrate vias would reduce the electrical resistance between the first redistribution layer 151 and the second redistribution layer, which are the redistribution layer arranged on the top side of the substrate and the redistribution layer which is arranged on the bottom side of the substrate. A person skilled in the art would understand that “arranged on the top side” or “arranged on the bottom side” does not indicate that the redistribution layer is directly arranged on substrate, but rather on a layer or via contact arranged on a top side and/or bottom side of the substrate. The first redistribution layer 151 covers the through substrate vias. The through substrate vias 141 are visible on FIG. 10B for illustration purposes but are located below the redistribution layer. This is shown on FIG. 10A, wherein the first 151 and the second redistribution layers 152 covers the through substrate vias 141.

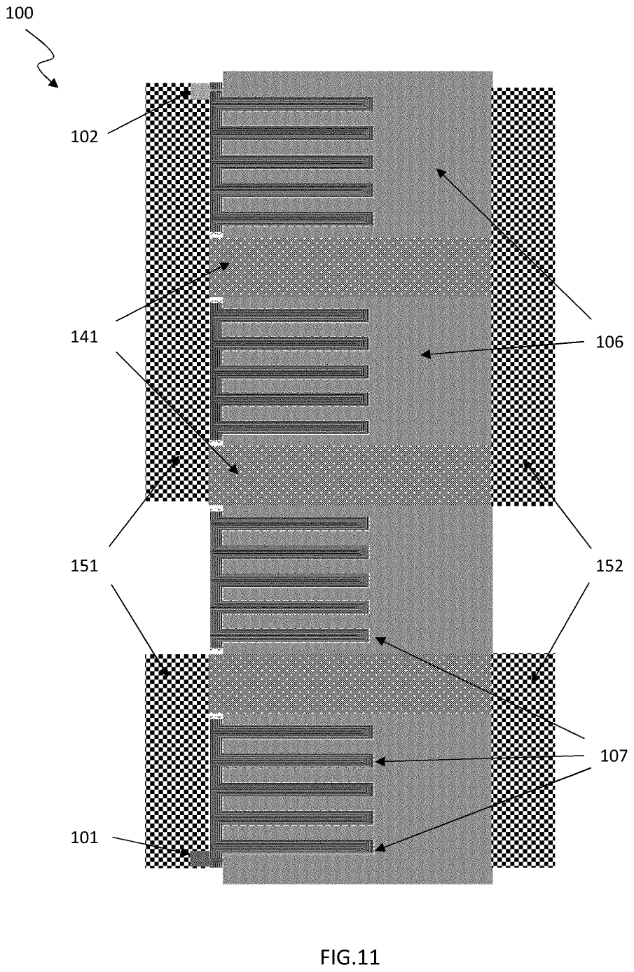

FIG. 11 shows an embodiment of a schematic view of the integrated capacitor, comprising multiple trenches 107 and through substrate vias 141 connecting redistribution layers 151 152 arranged on both sides of the substrate 106. FIG. 11 shows an embodiment wherein the multilayer stack is not deposited on the inner surfaces of the at least one through substrate via 141, but rather within the at least one trench 107, as disclosed and described in some embodiments of the present disclosure. The through substrate vias 141 are used in this embodiment to connect the first redistribution layer 151 to the second redistribution layer 152. The through substrate trenches do not have the multilayer stack deposited on the inner surfaces of the through substrate trenches before the through-substrate via material is filled within the through substrate trenches. An electrical connection flexibility is achieved in regards to the electrical connection of the integrated capacitor 100, since one port can be connected on the top side of the integrated capacitor while the other port can be connected to the bottom side of the integrated capacitor. This advantageously allows a flexibility for 3D integration of such integrated capacitor 100 since the integrated capacitor can be connected to external devices from both sides, thereby allowing a stacking of electronic components. The first terminal 101 and the second terminal 102 are arranged on one side of the redistribution layer, which is in this embodiment the first redistribution layer 151, since the multilayer stack is arranged on one side of the substrate. The through substrate vias 141 performs the electrical connection of the first and/or the second terminals of the integrated capacitor with the redistribution layer arranged on the other side of the substrate 106, which is the second redistribution layer 152.

In another aspect, a method of manufacturing an integrated capacitor on a substrate is disclosed, where the method may comprise the steps of: creating at least one trench in the substrate; arranging a multilayer stack on the substrate comprising at least three electrically conductive layers and separated by electrically isolative layers, and wherein the multilayer stack comprises a first set of odd layers and a second set of even layers, and wherein the multilayer stack is arranged in both a substantially vertical and a substantially horizontal direction along a plurality of surfaces of the substrate; creating at least two trenches in the multilayer stack down to a lowest layer of the multilayer stack, thereby defining at least a first and a second terminal trench; removing a substantial portion of the first set of odd layers within the first terminal trench; removing a substantial portion of the second set of even layers within the second terminal trench; arranging a secondary electrically conductive layer on the multilayer stack, and wherein the secondary electrically conductive layer is further arranged within the at least first and second terminal trench and in contact with the first set of odd layers and the second set of even layers; removing a substantial part of the secondary electrically conductive layer such that the first terminal is electrically isolated from the second terminal.

Advantageously, a substantial portion of the first set of odd layers or the second set of even layers can be selectively etched. By selectively etching either the first set of odd layers or the second set of even layers in the same trench, a collapsing of the metal layers creates an isolation of the non-etched metal layers with the trench. For instance, by selectively etching the first set of odd layers within the first terminal trench, the second set of even layers may collapse due to the weight and isolate the second set of even layers from the trench, and further advantageously, the dielectric set between the first set of odd layers and the second set of even layers may remain, such that the first set of odd layers can still be electrically isolated from the second set of even layers.

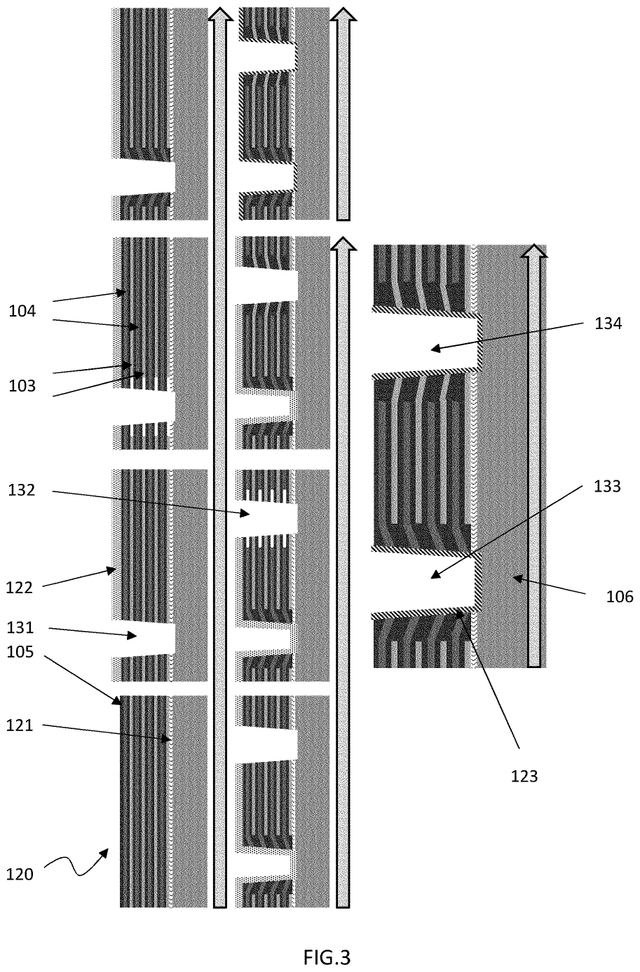

FIG. 3 shows an embodiment of a schematic view of the steps of the method as disclosed in the current disclosure. A multilayer stack 120 is deposited on the substrate 106, where the multilayer stack comprises an insulator layer 121, and 8 electrically conductive layers separated by electrically isolative layers 105, i.e. dielectric layers. The multilayer stack comprises a first set of odd layers 103 and a second set of even layers 104, where the first set of odd layers have different properties than the second set of even layers. A photoresist layer 122 is arranged on top of the multilayer stack with the help of a mask that would define the pattern where the photoresist layer should be deposited. The photoresist layer is removed from the areas where a first trench 131 is created. The first trench 131 is created by etching the multilayer stack, down to a lowest layer of the multilayer stack. The first trench can also be created down to the substrate. In that case, there would be no electrical isolation between the conductive layers and the substrate. This would potentially create a high coupling and potentially a leakage. A selective etching is performed where the selective etching substantially removes a portion of the first set of odd layers in the multilayer stack, from the first trench. Because of the mechanical structure of the multilayer stack, this selective etching of a substantial portion of the first set of odd layers makes the second set of even layers to collapse. This creates an electrical isolation of the first set of odd layers within the first trench, while maintaining the electrical isolation between the electrically conductive layers of the multilayer stack. A photoresist layer 122 can be deposited on the structure, where the photoresist layer is removed where a second trench 132 is created. A substantial portion of the second set of even layers can then be selectively etched from the second trench. Because of the mechanical structure of the multilayer stack, this selective etching of a substantial portion of the second set of even layers makes the first set of odd layers to collapse. This creates an electrical isolation of the second set of even layers within the second trench, while maintaining the electrical isolation between the electrically conductive layers of the multilayer stack. A secondary electrically conductive layer 123 can be arranged on top of the structure comprising the two trenches, where the secondary electrically conductive layer has an electrical contact with the second set of even layers in the first trench and the first set of odd layers in the second trench, thereby creating a first terminal 133 and a second terminal 134. A portion of the secondary electrically conductive layer is then removed in order to electrically isolate the first terminal from the second terminal.

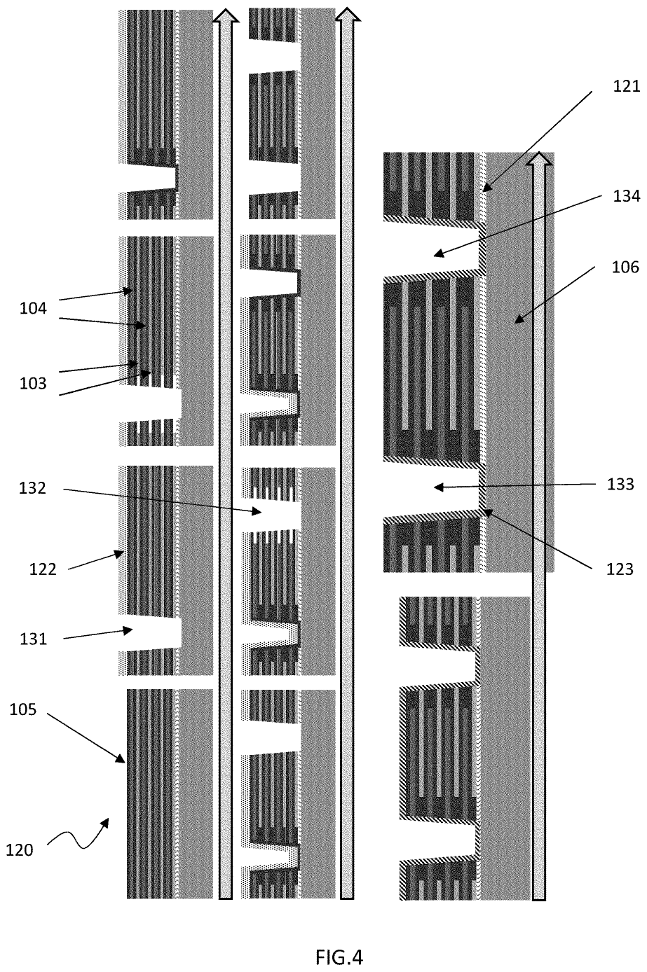

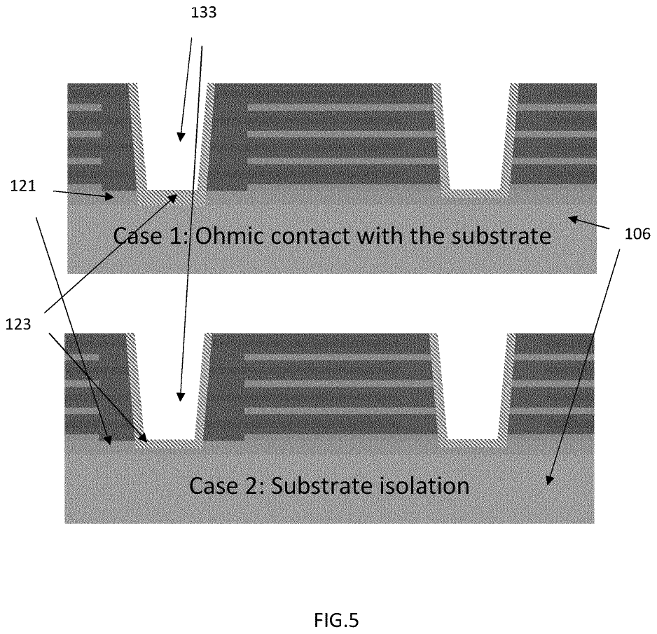

FIG. 4 shows an embodiment of a schematic view of the steps of the method as disclosed in the current disclosure. A multilayer stack 120 is deposited on the substrate 106, where the multilayer stack comprises an insulator layer 121, and 8 electrically conductive layers separated by electrically isolative layers 105, i.e. dielectric layers. The multilayer stack comprises a first set of odd layers 103 and a second set of even layers 104, where the first set of odd layers have different properties than the second set of even layers. A photoresist layer 122 is arranged on top of the multilayer stack with a mask, where the photoresist layer is removed from the areas where a first trench 131 is created. The first trench is then created by etching the multilayer stack, down to a lowest layer of the multilayer stack. The first trench can also be created down to the substrate. In that case, there would be no electrical isolation between the conductive layers and the substrate. This would potentially create a high coupling and potentially a leakage. A selective etching is performed where the selective etching substantially removes a portion of the first set of odd layers in the multilayer stack, from the first trench. Because of the mechanical structure of the multilayer stack, this selective etching of a substantial portion of the first set of odd layers does not make the second set of even layers to collapse, due to its thickness. Therefore, a dielectric layer is deposited within the first trench in order to electrically isolate the first set of odd layers to the first trench. Preferably, the dielectric layer can be deposited within the first trench by using a deposition method that can deposit conformally a layer, such that an atomic layer deposition (ALD). A photoresist layer can be deposited on the structure, where the photoresist layer is removed where a second trench 132 is created. A substantial portion of the second set of even layers can then be selectively etched from the second trench. Because of the mechanical structure of the multilayer stack, this selective etching of a substantial portion of the second set of even layers does not make the first set of odd layers to collapse. Therefore, a dielectric layer is deposited within the second trench in order to electrically isolate the second set of even layers to the second trench. Preferably, the dielectric layer can be deposited within the second trench by using a deposition method that can deposit conformally a layer, such that an atomic layer deposition (ALD). This creates an electrical isolation of the second set of even layers within the second trench, while maintaining the electrical isolation between the electrically conductive layers of the multilayer stack. A secondary electrically conductive layer 123 can be arranged on top of the structure comprising the two trenches, where the secondary electrically conductive layer has an electrical contact with the second set of even layers in the first trench and the first set of odd layers in the second trench, thereby creating a first terminal 133 and a second terminal 134. A portion of the secondary electrically conductive layer is then removed in order to electrically isolate the first terminal from the second terminal.

The integrated capacitor manufactured by the method disclosed herein may be any of the integrated capacitor as disclosed herein.

In yet another aspect, a method of manufacturing a via connecting at least two layers comprised in a multilayer stack of at least three layers arranged on a substrate. The method may comprise the steps of: arranging a multilayer stack on the substrate comprising at least three electrically conductive layers and separated by electrically isolative layers, and wherein the multilayer stack comprises a first set of odd layers and a second set of even layers; creating at least one trench in the multilayer stack down to a lowest layer of the multilayer stack; removing a substantial portion of the first set of odd layers or the second set of even layers through the at least one trench; arranging a secondary electrically conductive layer on the multilayer stack, and wherein the secondary electrically conductive layer is further arranged within the at least one trench and in contact with the first set of odd layers or the second set of even layers.

FIG. 3 or FIG. 4 show an embodiment of a schematic view of the steps of the method for manufacturing a via connecting at least two layers comprised in a multilayer stack. The via can be manufactured following parts of the method previously described in the current disclosure where a method of manufacturing an integrated capacitor on a substrate is described.

The multilayer stack and the substrate may be any of the multilayer stack and any of the substrate described herein. The via as described in the method can be any of the vias described in the current disclosure.

FIG. 5 shows an embodiment of a schematic view of two cases, where a first case shows an embodiment of a schematic view where one of the terminals has an ohmic contact with the substrate and a second case shows an embodiment of a schematic view where both terminals have a substrate isolation. The case 1 shows a schematic view where the first trench 133 is created down to the substrate 106, where the insulator layer 121 is also removed by the etching process that creates the first trench 133. When the secondary electrically conductive layer 123 is deposited in the first trench 133, an electrical connection is performed between the secondary electrically conductive layer 123 and the substrate 106 through an ohmic contact. The case 2 shows a schematic view where the first trench 133 is created down to a lowest layer of the substrate, where the insulator layer 121 is partially or not removed by the etching process that creates the first trench 133. This isolates the secondary electrically conductive layer 123 from the substrate 106.

The case 1 or first case, as described above and shown in FIG. 5, may be used in applications where an efficient decoupling may be needed between the first terminal and an external device connected to the first terminal.

In another aspect, an integrated capacitor device is disclosed. The integrated capacitor device may comprise the integrated capacitor as described herein and at least two external terminals. The at least two external terminals can be connected to the at least first and second terminals of the integrated capacitor as described in the current disclosure. Preferably, the integrated capacitor device may be a surface mount device (SMD) component. SMD components are electronic component that can be mounted directly onto the surface of a printed circuit board (PCB) or any other surfaces that can accept electronic components. SMD components are suitable for high-density circuit boards. SMD components can be in a variety of sizes, ranging from the relatively large 1206 size to the tiny 0201 size. The integrated capacitor device can be a SMD component with a size in the range of size as described herein.

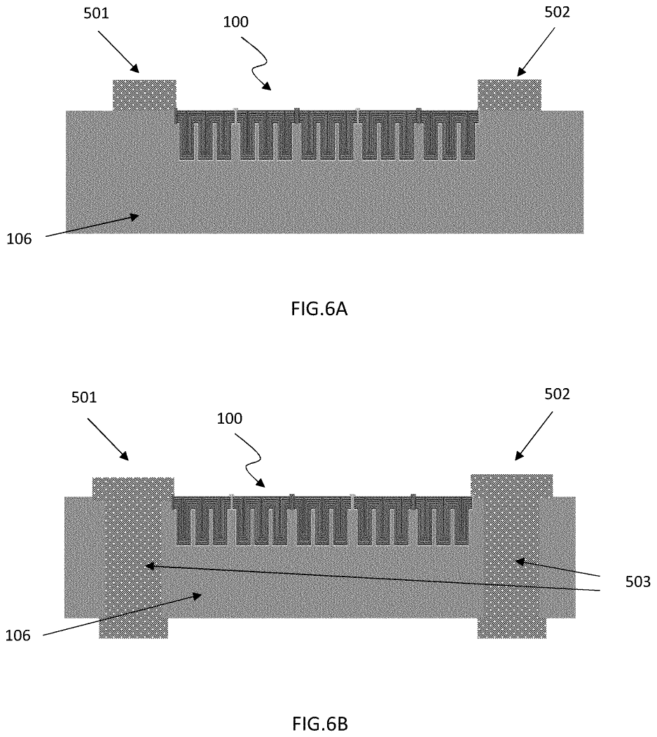

FIG. 6A shows an embodiment of a schematic view of the integrated capacitor with external terminals 500. The external terminals 501 502 are arranged on the top side of the substrate 106, where the integrated capacitor is also processed. The external terminals are in electrical contact with the first and second terminal of the integrated capacitor. Preferably, the external terminals may be thick enough to sustain mechanical constraints due to bonding or any other methods such as soldering, of electrically connecting the external terminals to any external devices, PCBs, or dies.

In another aspect, an integrated capacitor device is disclosed where the integrated capacitor device may comprise at least one integrated capacitor as disclosed in the current disclosure; one or more vias, such as through substrate vias, arranged in the substrate and connected to the at least first and second terminals of the at least one integrated capacitor, and wherein the through substrate vias can provide a plurality of terminals on both sides of the substrate. Advantageously, the through substrate vias can be arranged on the sides of the integrated capacitor such that the through substrate vias may not interfere with the integrated capacitor structure. Preferably, a redistribution layer may be arranged from the at least first and second terminals of the integrated capacitor such that the redistribution layer can connect the at least first and second terminals to the through substrate vias.

FIG. 6B shows an embodiment of a schematic view of the integrated capacitor with external terminals 500, where the external terminals 501 502 are arranged on both sides of the substrate 106 with through substrate vias 503. The through substrate vias 503 are arranged on both sides of the integrated capacitor, such that the through substrate vias do not cross the integrated capacitor, but preferably cross the substrate on the sides of the integrated capacitor. The through substrate vias are connected to the first and the second terminal of the integrated capacitor, such that an electrical connection is performed between the first and the second terminal of the integrated capacitor and the through substrate vias.

In yet another aspect, an integrated circuit assembly is disclosed where the integrated circuit assembly may comprise at least one integrated circuit; at least one integrated capacitor as disclosed herein; wherein the at least one integrated circuit and the at least one integrated capacitor may be integrated and electrically connected in the substrate, and wherein the integrated circuit assembly can further comprise at least two external terminals.

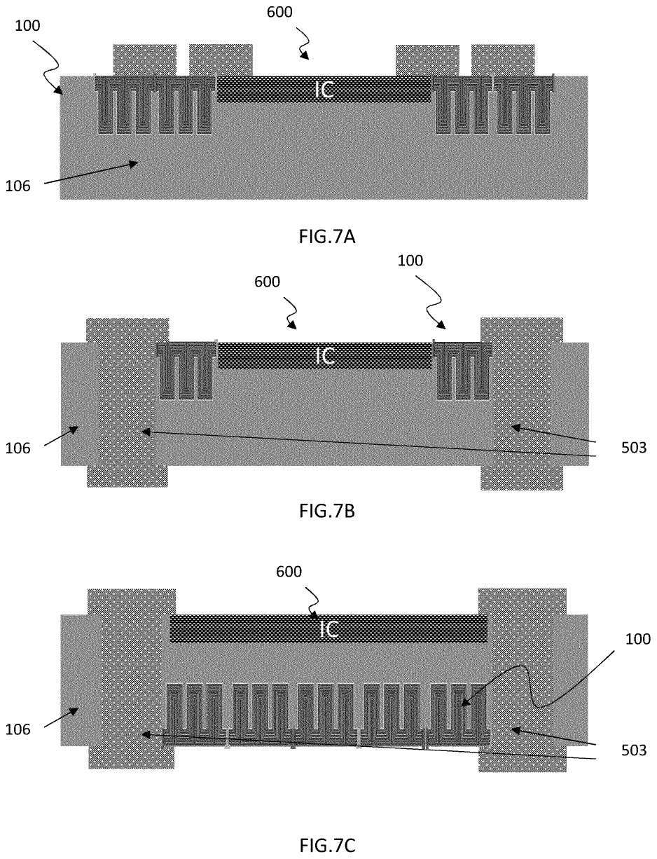

FIG. 7A shows an embodiment of a schematic view of the integrated capacitor 100 integrated with an integrated circuit 600 in a substrate 106. This embodiment shows two integrated capacitors 100, where one integrated capacitor is arranged on each side of the integrated circuit, and both being on one side of the substrate 106. Some terminals are arranged on top of the substrate in order to electrically connect the integrated capacitors with the integrated circuit or to provide an option of electrically connecting the different terminals to external devices, dies or PCBs. By having integrated capacitors on both side of the integrated circuit and integrated within the same substrate, an efficient decoupling can be processed without arranging bulky capacitors, such as SMD capacitors with a large capacitance value. The close proximity of the capacitors to the integrated circuit can offer less noise and improved electromagnetic compatibility.

In one aspect, an integrated circuit assembly may comprise at least one integrated circuit; at least one integrated capacitor as disclosed herein; one or more vias, such as through substrate vias, preferably arranged in the substrate and connected to the at least first and second terminals of the at least one integrated capacitor as defined herein and/or to the at least one integrated circuit, and wherein the through substrate vias can provide a plurality of external terminals on both sides of the substrate.

FIG. 7B-C show embodiments of schematic views of the integrated capacitor 100 integrated with an integrated circuit 600 in a substrate 106, and where the external terminals are part of through substrate vias 503. The through substrate vias allow an electrical connection on both sides of the substrate. FIG. 6C shows an embodiment where the integrated capacitor is arranged on one side of the substrate while the integrated circuit is arranged within the substrate but on the other side of the substrate. This allows a short connection between the integrated capacitor and the integrated circuit, while reducing the footprint of the substrate.

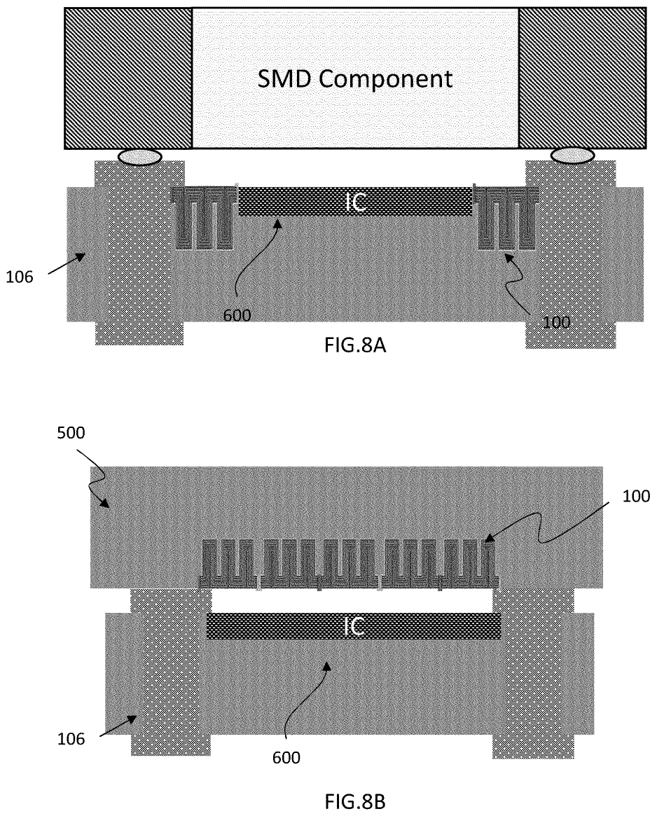

FIG. 8A-B show embodiments of schematic views of possible applications of the integrated capacitor in stacked electronic assembly. FIG. 8A shows an embodiment of a schematic view where a SMD component is stacked on top of the integrated capacitor 100 integrated with an integrated circuit 600 in a substrate 106. The SMD component is soldered on the through substrate vias. FIG. 8B shows an embodiment of a schematic view where the integrated capacitor device 500 is stacked on top of a substrate 106 comprising an integrated circuit 600 and through substrate vias. In this embodiment, the integrated capacitor device 500 is used as a SMD component where the external terminals of the integrated capacitor device are soldered on the through substrate vias of the substrate comprising the integrated circuit, thereby electrically connecting the integrated capacitor device and the integrated circuit.

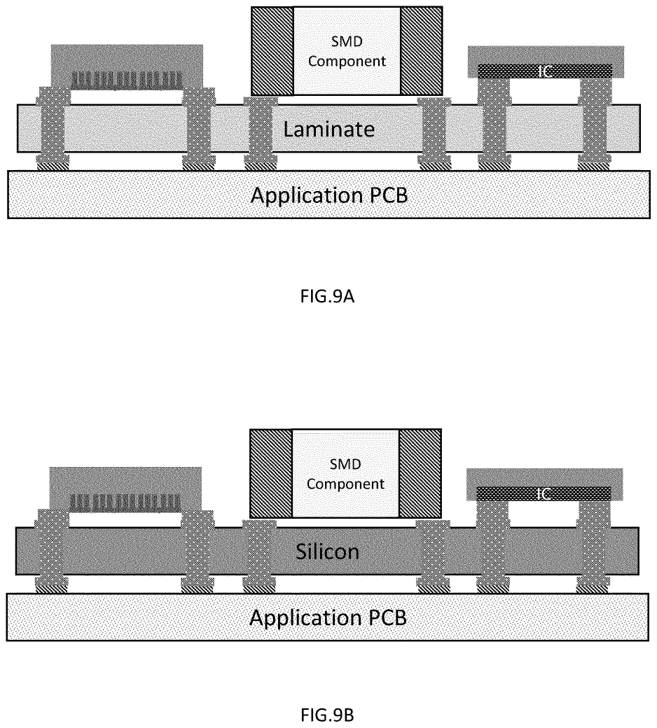

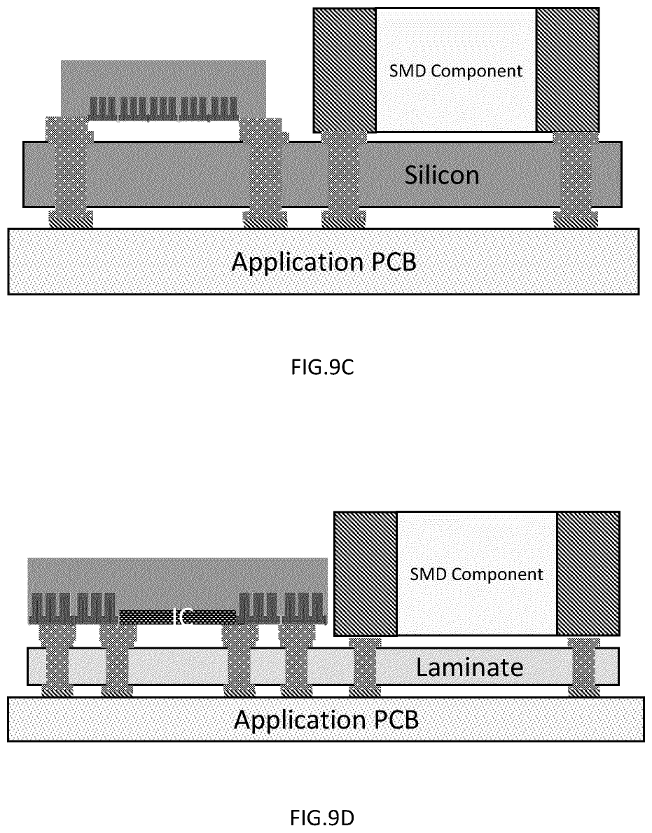

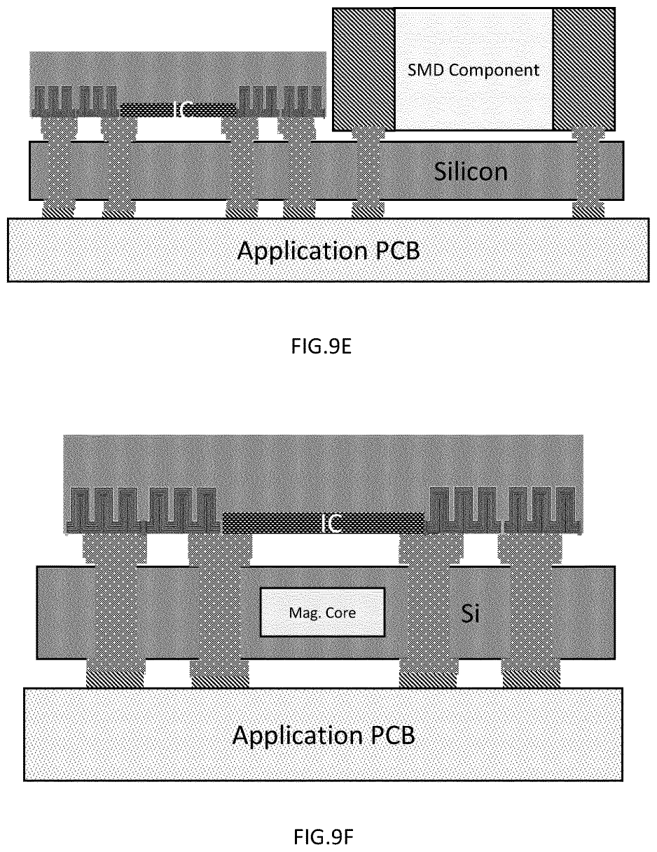

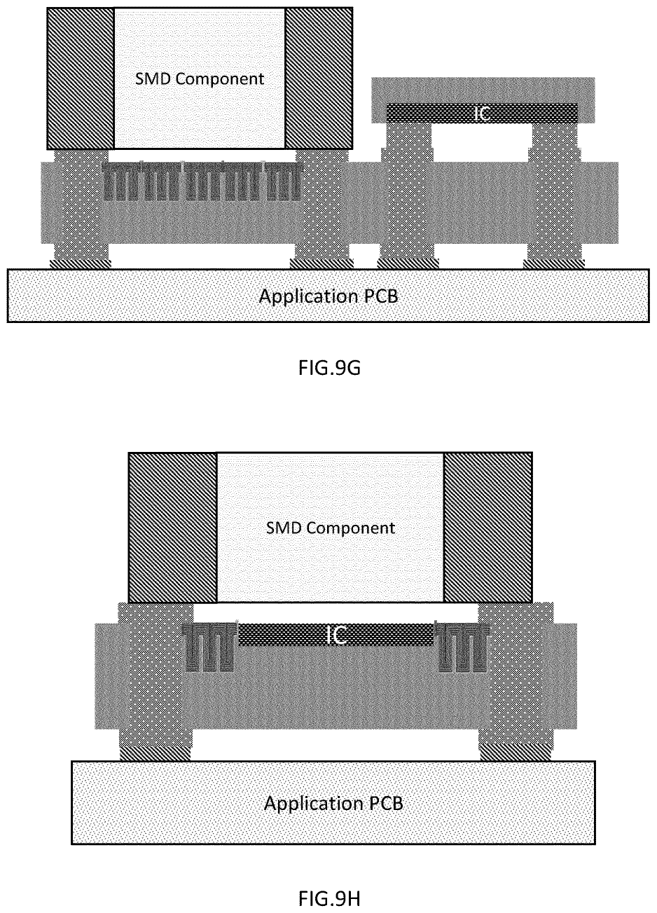

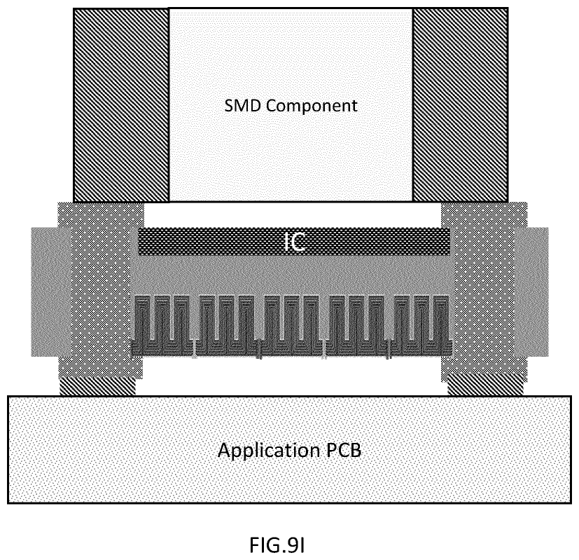

FIG. 9A-I show embodiments of schematic views of possible applications of the integrated capacitor in stacked electronic assembly. FIG. 9A shows an embodiment of a schematic view of the integrated capacitor device that is stacked on top of a laminate and an application PCB. The integrated capacitor device is soldered via the external terminals on through substrate vias within the laminate that are further connected on the other side of the laminate to the application PCB. Preferably, the application PCB may provide internal electrical routing so that the integrated capacitor can be electrically connected to either the SMD components or the integrated circuit, or both. FIG. 9B shows an embodiment of a schematic view similar to the one shown in FIG. 9A, but where the laminate is replaced by a silicon substrate. The silicon substrate may allow a better thermal dissipation than the laminate substrate. A silicon substrate may present an advantage of being more suitable for integrating dies or more generally electronic components and/or devices within the substrate. FIG. 9C shows an embodiment of a schematic view of an integrated circuit that is integrated within the silicon substrate, and wherein the silicon substrate comprises through substrate vias which allows an electrical connection on both sides of the silicon substrate. The integrated capacitor is arranged on top of the silicon substrate, as close as possible to the integrated circuit such that different parasitics that can be provided by a long routing length between the integrated circuit and the integrated capacitor can be substantially removed. FIG. 9D shows an embodiment of a schematic view of a stacked electronic assembly where the integrated circuit assembly comprising the integrated capacitor is stacked on top of a laminate substrate, and further stacked on top of an application PCB. FIG. 9E shows an embodiment of a schematic view of a stacked electronic assembly where the integrated circuit assembly comprising the integrated capacitor and an integrated circuit within a substrate, that is stacked on top of a secondary silicon substrate, and further stacked on top of an application PCB. The silicon substrate provides through substrate vias to allow a direct electrical connection from one side of the silicon substrate to the other side of the silicon substrate. FIG. 9F shows an embodiment of a schematic view of a stacked electronic assembly where the integrated circuit assembly comprising the integrated capacitor and an integrated circuit comprised within a substrate is stacked on top of a secondary silicon substrate, and further stacked on top of an application PCB. The secondary silicon substrate comprises through substrate vias which allows an electrical connection from one side of the secondary silicon substrate to the other side of the secondary silicon substrate. The secondary silicon substrate comprised a magnetic core, such as a coil, which is integrated within the secondary silicon substrate. FIG. 9G shows an embodiment of a schematic view of a stacked electronic assembly where an integrated circuit and a SMD component is stacked on a substrate comprising the integrated capacitor, and wherein the substrate further comprises through substrate vias to allow an electrical connection between one side of the substrate to the other side of the substrate, where an application PCB is connected on the other side. FIG. 9H shows an embodiment of a schematic view of a stacked electronic assembly where an integrated circuit assembly comprising an integrated circuit and two integrated capacitor that are arranged within the substrate on each side of the integrated circuit. The substrate further comprises through substrate vias, such that a SMD component can be arranged on one side of the substrate while an application PCB is arranged on the other of the substrate. FIG. 9I shows an embodiment of a schematic view of a stacked electronic assembly comprising an integrated circuit assembly, a SMD component and an application PCB. The integrated circuit assembly comprises on one side an integrated circuit integrated within a substrate and where the substrate comprises through substrate vias that electrically connect the integrated circuit with the integrated capacitor integrated on the other side within the substrate. The integrated circuit assembly is stacked on top of an application PCB, and a SMD component is stacked on top of the integrated circuit assembly.

### Embodiment List

Disclosed herein are the following embodiments

1. An integrated capacitor on a substrate comprising:
at least one trench within the substrate;
a multilayer stack comprising at least three electrically conductive layers deposited on the substrate and separated by electrically isolative layers, and wherein the multilayer stack comprises a first set of odd layers and a second set of even layers, and wherein the multilayer stack is arranged in both a substantially vertical and a substantially horizontal direction along a plurality of surfaces of the substrate;
at least a first and a second terminal, wherein the first terminal is in contact with the first set of odd layers and the second terminal is in contact with the second set of even layers.

2. The integrated capacitor according to item 1, wherein the substrate is a semiconductor substrate, a glass substrate, a sapphire substrate or a polyamide substrate.

3. The integrated capacitor according to any one of the preceding items, wherein the multilayer stack comprises at least four, preferably at least five, more preferably at least ten, even more preferably at least fifteen, most preferably at least twenty electrically conductive layers.

4. The integrated capacitor according to any one of the preceding items, wherein the integrated capacitor comprises at least two trenches, preferably at least three trenches, more preferably at least four trenches within the substrate.

5. The integrated capacitor according to any one of the preceding items, wherein the at least one trench has an opening width in the range of 0.1 μm to 10 μm.

6. The integrated capacitor according to any one of the preceding items, wherein the at least one trench has a depth in the range of 10 μm to 725 μm.

7. The integrated capacitor according to any one of the preceding items, wherein the integrated capacitor comprises at least three terminals, preferably at least five terminals, more preferably at least ten terminals, even more preferably at least twenty terminals.

8. The integrated capacitor according to any one of the preceding items, wherein the at least first and second terminal are vias.

9. The integrated capacitor according to item 8, wherein the vias have a redistribution layer.

10. The integrated capacitor according to any one of items 8-9, wherein the redistribution layer is arranged on an upper surface of the vias, and wherein the upper surface of the vias is substantially arranged at the same height than an upper surface of the multilayer stack.

11. The integrated capacitor according to any one of items 8-10, wherein the diameter of the vias is in the range of 1 to 50 μm.

12. The integrated capacitor according to any one of items 8-11, wherein the thickness of the redistribution layer is in the range of 1 to 30 μm.

13. The integrated capacitor according to any one of items 8-12, wherein the vias are through substrate vias.

14. The integrated capacitor according to any one of the preceding items, wherein the at least first and second terminal are configured to be deposited with a secondary electrically conductive layer.

15. The integrated capacitor according to item 14, wherein the secondary electrically conductive layer is made with copper (Cu).

16. The integrated capacitor according to any one of items 14-15, wherein the secondary electrically conductive layer is configured to be deposited with a seed layer comprising an adhesion layer and a seed metal layer or deposited with an electroless nickel immersion gold (ENIG) method comprising a seed layer.

17. The integrated capacitor according to any one of the preceding items, wherein the electrically conductive layers are made with copper (Cu), gold (Au), chrome (Cr), titanium (Ti), platinum (Pt), aluminium (Al), tantalum (Ta), titanium carbide (TiC), titanium nitride (TiN), tantalum (Ta), tantalum nitride (TaN), Ti-doped zinc oxide (TZO) and/or Al-doped zinc oxide (AZO).

18. The integrated capacitor according to any one of the preceding items, wherein the electrically conductive layers are configured to be deposited with a deposition method such as evaporation, sputtering or atomic layer deposition.

19. The integrated capacitor according to any one of the preceding items, wherein the thickness of the electrically conductive layers is in the range of 5 to 500 nm.

20. The integrated capacitor according to any one of the preceding items, wherein one or more of the electrically isolative layers is a dielectric layer.

21. The integrated capacitor according to item 20, wherein the dielectric layer is made with silicon dioxide (SiO₂), silicon nitride (Si₃N₄), aluminium oxide (Al₂O₃), aluminium nitride (AlN), hafnium oxide (HfO₂) or titanium dioxide (TiO₂).

22. The integrated capacitor according to any one of the preceding items, wherein the thickness of the dielectric layer is in the range of 5 to 3000 nm.

23. The integrated capacitor according to any one of the preceding items, wherein the integrated capacitor comprises a secondary electrically isolative layer.

24. The integrated capacitor according to item 23, wherein the secondary electrically isolative layer is arranged between the substrate and the multilayer stack.

25. The integrated capacitor according to any one of the preceding items, wherein the secondary electrically isolative layer is an insulator layer.

26. The integrated capacitor according to item 25, wherein the insulator layer is made with silicon dioxide (SiO₂), silicon nitride (Si₃N₄), aluminium oxide (Al₂O₃) or aluminium nitride (AlN).

27. The integrated capacitor according to any one of the preceding items, wherein the thickness of the insulator layer is in the range of 5 to 3000 nm.

28. The integrated capacitor according to any one of the preceding items, wherein the electrically isolative layers are configured to be deposited with a secondary deposition method such as thermal oxidation, evaporation, sputtering, atomic layer deposition or chemical vapor deposition.

29. The integrated capacitor according to any one of the preceding items, wherein the semiconductor substrate is a silicon substrate, a gallium nitride (GaN) substrate, a silicon carbide (SIC) substrate or a gallium arsenide (GaAs) substrate

30. The integrated capacitor according to any one of the preceding items, wherein the thickness of the substrate is in the range of 50 to 750 μm.

31. The integrated capacitor according to any one of the preceding items, further comprising a diffusion barrier layer.

32. The integrated capacitor according to item 31, wherein the diffusion barrier layer is arranged between the insulator layer and the multilayer stack.

33. The integrated capacitor according to any one of items 31-32, wherein the diffusion barrier layer has a thickness in the range of 5 to 100 nm.

34. The integrated capacitor according to any one of the preceding items, wherein the at least one trench is at least one through substrate trench, and wherein the through substrate trench is configured to be etched through the substrate.

35. The integrated capacitor according to any one of the preceding items, wherein the multilayer stack is configured to be deposited on a first side and a second side of the substrate.

36. The integrated capacitor according to any one of the preceding items, wherein the first side and the second side of the substrate are opposite sides of the substrate.

37. The integrated capacitor according to any one of the preceding items, wherein the multilayer stack is configured to be deposited on lateral surfaces of the at least one through substrate trench, and such as the multilayer stack is configured to be connected from the first side to the second side through the at least one through substrate trench.

38. The integrated capacitor according to item 37, wherein the lateral surfaces of the at least one through substrate trench are inner lateral surfaces of the at least one through substrate trench.

39. The integrated capacitor according to any one of the preceding items, wherein the at least one through substrate trench is configured to be filled with a through-substrate via material, such as the substrate comprises at least one through-substrate via.

40. The integrated capacitor according to any one of the preceding items, wherein the at least one through-substrate via is configured to be connected to the redistribution layer.

41. The integrated capacitor according to any one of the preceding items, wherein the redistribution layer comprises a first redistribution layer and a second redistribution layer.

42. The integrated capacitor according to any one of the preceding items, wherein the first redistribution layer is arranged on the first side of the substrate and the second redistribution layer is arranged on the second side of the substrate.

43. The integrated capacitor according to any one of the preceding items, wherein the redistribution layer comprises the at least first and/or second terminal.

44. A method of manufacturing an integrated capacitor on a substrate comprising the steps of:
creating at least one trench in the substrate;
arranging a multilayer stack on the substrate comprising at least three electrically conductive layers and separated by electrically isolative layers, and wherein the multilayer stack comprises a first set of odd layers and a second set of even layers, and wherein the multilayer stack is arranged in both a substantially vertical and a substantially horizontal direction along a plurality of surfaces of the substrate;
creating at least two trenches in the multilayer stack down to a lowest layer of the multilayer stack, thereby defining at least a first and a second terminal trench;
removing a substantial portion of the first set of odd layers within the first terminal trench;
removing a substantial portion of the second set of even layers within the second terminal trench;
arranging a secondary electrically conductive layer on the multilayer stack, and wherein the secondary electrically conductive layer is further arranged within the at least first and second terminal trench and in contact with the first set of odd layers and the second set of even layers;
removing a substantial part of the secondary electrically conductive layer such that the first terminal is electrically isolated from the second terminal.

45. The method according to item 44, wherein the at least two trenches in the multilayer stack are created down to the substrate.

46. The method according to any one of items 44-45, wherein the integrated capacitor is the integrated capacitor according to any one of items 1-43.

47. A method of manufacturing a via connecting at least two layers comprised in a multilayer stack of at least three layers arranged on a substrate, the method comprising the steps of:
arranging a multilayer stack on the substrate comprising at least three electrically conductive layers and separated by electrically isolative layers, and wherein the multilayer stack comprises a first set of odd layers and a second set of even layers;
creating at least one trench in the multilayer stack down to a lowest layer of the multilayer stack;
removing a substantial portion of the first set of odd layers or the second set of even layers through the at least one trench;
arranging a secondary electrically conductive layer on the multilayer stack, and wherein the secondary electrically conductive layer is further arranged within the at least one trench and in contact with the first set of odd layers or the second set of even layers.

48. The method according to item 47, wherein the at least one trench in the multilayer stack is created down to the substrate.

49. The method according to any one of items 47-48, wherein the multilayer stack and the substrate are the multilayer stack and the substrate according to any one of items 1-43, and wherein the via is the via according to any one of items 8-13.

50. An integrated capacitor device comprising the integrated capacitor according to any one of items 1-43 and at least two external terminals, wherein the at least two external terminals are connected to the at least first and second terminals of the integrated capacitor according to any one of items 1-43.

51. An integrated capacitor device comprising:
at least one integrated capacitor as defined in any one of items 1-43;
one or more vias, such as through substrate vias, arranged in the substrate and connected to the at least first and second terminals of the at least one integrated capacitor as defined in any one of items 1-43, and wherein the through substrate vias provide a plurality of terminals on both sides of the substrate.

52. An integrated circuit assembly comprising:
at least one integrated circuit;
at least one integrated capacitor as defined in any one of items 1-43;
wherein the at least one integrated circuit and the at least one integrated capacitor are integrated and electrically connected in the substrate, and wherein the integrated circuit assembly further comprises at least two external terminals.

53. An integrated circuit assembly comprising:
at least one integrated circuit;
at least one integrated capacitor as defined in any one of items 1-43;
one or more vias, such as through substrate vias, arranged in the substrate and connected to the at least first and second terminals of the at least one integrated capacitor as defined in any one of items 1-43 and/or to the at least one integrated circuit, and wherein the through substrate vias provide a plurality of external terminals on both sides of the substrate.

1. An integrated capacitor on a substrate comprising:
at least one trench within the substrate;
a multilayer stack comprising at least three electrically conductive layers deposited on the substrate and separated by electrically isolative layers, and wherein the multilayer stack comprises a first set of odd layers and a second set of even layers, and wherein the multilayer stack is arranged in both a substantially vertical and a substantially horizontal direction along a plurality of surfaces of the substrate;
at least a first and a second terminal, wherein the first terminal is in contact with the first set of odd layers and the second terminal is in contact with the second set of even layers.

2. The integrated capacitor according to claim 1, wherein the substrate is a semiconductor substrate, a glass substrate, a sapphire substrate or a polyamide substrate, and wherein the semiconductor substrate is a silicon substrate, a gallium nitride (GaN) substrate, a silicon carbide (SIC) substrate or a gallium arsenide (GaAs) substrate.

3. The integrated capacitor according to any one of the preceding claims, wherein the multilayer stack comprises at least four, preferably at least five, more preferably at least ten, even more preferably at least fifteen, most preferably at least twenty electrically conductive layers.

4. The integrated capacitor according to any one of the preceding claims, wherein the integrated capacitor comprises at least two trenches, preferably at least three trenches, more preferably at least four trenches within the substrate.

5. The integrated capacitor according to any one of the preceding claims, wherein the integrated capacitor comprises at least three terminals, preferably at least five terminals, more preferably at least ten terminals, even more preferably at least twenty terminals.

6. The integrated capacitor according to any one of the preceding claims, wherein the at least first and second terminal are vias, and wherein the vias are through substrate vias.

7. The integrated capacitor according to any one of the preceding claims, wherein the at least first and second terminal are configured to be deposited with a secondary electrically conductive layer, and wherein the secondary electrically conductive layer is made with copper (Cu).

8. The integrated capacitor according to any one of the preceding claims, wherein the electrically conductive layers are made with copper (Cu), gold (Au), chrome (Cr), titanium (Ti), platinum (Pt), aluminium (Al), tantalum (Ta), titanium carbide (TiC), titanium nitride (TiN), tantalum (Ta), tantalum nitride (TaN), Ti-doped zinc oxide (TZO) and/or Al-doped zinc oxide (AZO), and wherein the electrically conductive layers are configured to be deposited with a deposition method such as evaporation, sputtering or atomic layer deposition.

9. The integrated capacitor according to any one of the preceding claims, wherein one or more of the electrically isolative layers is a dielectric layer, and wherein the dielectric layer is made with silicon dioxide (SiO₂), silicon nitride (Si₃N₄), aluminium oxide (Al₂O₃), aluminium nitride (AlN), hafnium oxide (HfO₂) or titanium dioxide (TiO₂).

10. The integrated capacitor according to any one of the preceding claims, wherein the at least one trench is at least one through substrate trench, and wherein the through substrate trench is configured to be etched through the substrate.

11. The integrated capacitor according to any one of the preceding claims, wherein the multilayer stack is configured to be deposited on a first side and a second side of the substrate, and wherein the first side and the second side of the substrate are opposite sides of the substrate.

12. The integrated capacitor according to any one of the preceding claims, wherein the multilayer stack is configured to be deposited on lateral surfaces of the at least one through substrate trench, and such as the multilayer stack is configured to be connected from the first side to the second side through the at least one through substrate trench, and wherein the lateral surfaces of the at least one through substrate trench are inner lateral surfaces of the at least one through substrate trench.

13. The integrated capacitor according to any one of the preceding claims, wherein the at least one through substrate trench is configured to be filled with a through-substrate via material, such as the substrate comprises at least one through-substrate via.

14. The integrated capacitor according to any one of the preceding claims, wherein the at least one through-substrate via is configured to be connected to the redistribution layer.

15. The integrated capacitor according to any one of the preceding claims, wherein the redistribution layer comprises a first redistribution layer and a second redistribution layer, and wherein the first redistribution layer is arranged on the first side of the substrate and the second redistribution layer is arranged on the second side of the substrate.

16. The integrated capacitor according to any one of the preceding claims, wherein the redistribution layer comprises the at least first and/or second terminal.

17. A method of manufacturing an integrated capacitor on a substrate comprising the steps of:
creating at least one trench in the substrate;
arranging a multilayer stack on the substrate comprising at least three electrically conductive layers and separated by electrically isolative layers, and wherein the multilayer stack comprises a first set of odd layers and a second set of even layers, and wherein the multilayer stack is arranged in both a substantially vertical and a substantially horizontal direction along a plurality of surfaces of the substrate;
creating at least two trenches in the multilayer stack down to a lowest layer of the multilayer stack, thereby defining at least a first and a second terminal trench;
removing a substantial portion of the first set of odd layers within the first terminal trench;
removing a substantial portion of the second set of even layers within the second terminal trench;
arranging a secondary electrically conductive layer on the multilayer stack, and wherein the secondary electrically conductive layer is further arranged within the at least first and second terminal trench and in contact with the first set of odd layers and the second set of even layers;
removing a substantial part of the secondary electrically conductive layer such that the first terminal is electrically isolated from the second terminal.

18. The method according to claim 17, wherein the at least two trenches in the multilayer stack are created down to the substrate.

19. The method according to any one of claims 17-18, wherein the integrated capacitor is the integrated capacitor according to any one of claims 1-16.

20. A method of manufacturing a via connecting at least two layers comprised in a multilayer stack of at least three layers arranged on a substrate, the method comprising the steps of:
arranging a multilayer stack on the substrate comprising at least three electrically conductive layers and separated by electrically isolative layers, and wherein the multilayer stack comprises a first set of odd layers and a second set of even layers;
creating at least one trench in the multilayer stack down to a lowest layer of the multilayer stack;
removing a substantial portion of the first set of odd layers or the second set of even layers through the at least one trench;
arranging a secondary electrically conductive layer on the multilayer stack, and wherein the secondary electrically conductive layer is further arranged within the at least one trench and in contact with the first set of odd layers or the second set of even layers.

21. The method according to claim 20, wherein the at least one trench in the multilayer stack is created down to the substrate.

22. The method according to any one of claims 20-21, wherein the multilayer stack, the substrate and the via are the multilayer stack, the substrate and the via according to any one of claims 1-16.
